(19) United States
(12) Patent Application Publication
(10) Pub. No.: US 2012/0025795 A1
(43) Pub. Date: Feb. 2, 2012

(54) COMPARATOR AND DC/DC CONVERTER

(76) Inventor: Heisuke Nakashima, Tokyo (JP)

(21) Appl. No.: 13/260,116

(22) PCT Filed: Mar. 10, 2010
(86) PCT No.: PCT/JP2010/053944

§ 371 Date: Sep. 23, 2011

(30) Foreign Application Priority Data
Mar. 23, 2009 (JP) 2009 069795

(51) Int. Cl. G05F 1/56; H03K 5/22

(52) U.S. Cl. 323/271; 327/67

(57) ABSTRACT

There is provided a PWM comparator which needs no current detecting differential amplifier in a control circuit constituting a current mode control DC/DC converter. The comparator includes a differential input stage including two pairs of input differential transistors whose sources are commonly connected for each pair; two constant-current sources connected to the common sources of the pairs of input differential transistors, respectively; a load transistor commonly connected to drain sides of the pairs and performing a current-voltage conversion; and an output stage connected to a point where the differential input stage and the load transistor are connected to each other. A feedback voltage of an output voltage and a slope compensating waveform signal are input to terminals, respectively, of one pair, and voltages at both ends of a current detecting resistor, which is connected in series to the inductor, are input to terminals, respectively, of the other pair.

### TECHNICAL FIELD

The present invention relates to a comparator suitable for a PWM comparator constituting a current mode control direct current/direct current (DC/DC) converter and to the DC/DC converter using the comparator.

### BACKGROUND ART

There is a switching regulator type DC/DC converter as a circuit that converts a DC input voltage and outputs a DC voltage having a potential different from that of the DC input voltage. Among such DC/DC converters, there is a DC/DC converter including a driving switching element that applies a DC voltage supplied from a DC power supply such as a battery to an inductor (coil) to allow a current to pass and thereby accumulates energy in the coil, a rectifying element that rectifies the current at the coil in an energy emission period in which the driving switching element is off, and a control circuit that performs on/off control on the driving switching element.

Conventionally, in the switching regulator type DC/DC converter, control is performed in such a way that an output voltage is detected by an error amplifier and fed back to a pulse width modulation (PWM) comparator or a pulse frequency modulation (PFM) comparator, and that a period of time in which the switching element is on is lengthened when the output voltage is decreased, and a period of time in which the switching element is on is shortened when the output voltage is increased.

In PWM control, a pulse width is changed according to a ratio of a Vin voltage and a Vout voltage while a period (frequency) of a driving pulse is kept constant, whereby the output voltage becomes constant. Among the PWM control DC/DC converters, there is a current mode control DC/DC converter in which control is performed in such a way that a current passing through the driving switching element or through the coil is detected and that the current detection signal is fed back to a voltage feedback loop. Examples of inventions relating to such a DC/DC converter are disclosed in Patent Documents 1 and 2.

### PRIOR ART DOCUMENTS

### Patent Documents

Patent Document 1: Japanese Patent Publication Laid-Open No. 2005-295631

Patent Document 2: Japanese Patent Publication Laid-Open No. 2007-159319

### DISCLOSURE OF INVENTION

### Problems to be Solved by the Invention

FIG. 5 illustrates an example of a configuration of current mode control DC/DC converter that was studied by the inventors. In the DC/DC converter of FIG. 5, a potential difference between a feedback voltage VFB of the output voltage and a reference voltage Vref is amplified by an error amplifier E-AMP and supplied to a PWM comparator CMP. Further, in the DC/DC converter of FIG. 5, and a voltage obtained based on the voltages at both terminals of a current sense resistor Rs connected between an input terminal IN and a coil driving switching transistor SW1 is amplified by a differential amplifier AMP, and input to the PWM comparator as a detection signal of the current passing through the coil.

A slope compensating sawtooth wave SAW is also input to the PWM comparator CMP, and a voltage obtained by adding the sawtooth wave SAW to an output of the current detecting differential amplifier AMP is compared to the output voltage of the error amplifier E-AMP. Specifically, the PWM comparator CMP is designed such that a high-level signal is output when the following expression (1) is positive (>0) and such that a low-level signal is output when the expression (1) is negative (<0):

Ki·Vs+Vsaw−Verr (1)

wherein Vs is a voltage between the terminals of the current sense resistor Rs, Ki is a gain of the current detecting differential amplifier AMP, Vsaw is an amplitude of the sawtooth wave SAW, and Verr is an output voltage of the error amplifier E-AMP. The slope compensation is a technique of controlling a slope of a change in the current feedback loop in order to prevent an oscillation of a feedback control system. The slope compensation is conventionally performed in the current mode control.

In the DC/DC converter of FIG. 5, a waveform of the current passing through the current sense resistor Rs rapidly changes. Therefore, a high slew rate is required in one of characteristics of the current detecting differential amplifier AMP. Additionally, the current detecting differential amplifier AMP is required to cover a wide band in order that the gain is not decreased even if the switching frequency is increased. However, it is difficult to obtain the differential amplifier having such characteristics. Such a differential amplifier causes problems in that a circuit scale is enlarged because a circuit having a complicated configuration is required, and that a process change is required in order to improve a characteristic of transistors constituting the circuit, resulting in a cost increase.

The present invention has been made in view of the foregoing. An object of the present invention is to provide a PWM comparator which obviates the need for a current detecting differential amplifier, which is a factor for the cost increase, in the current mode control DC/DC converter.

### Means for Solving Problems

To achieve the above object, an invention of the present application is configured as a comparator to be provided in a voltage control loop of a current mode control DC/DC converter including an inductor that is connected between a voltage input terminal to which a DC voltage is input and an output terminal to which a load is connected, a driving element that allows a current to pass through the inductor, the voltage control loop that controls the driving element according to a feedback voltage of an output voltage, and a loop that feeds back a detection signal of the current passing through the inductor to the voltage control loop, the comparator comprising: a differential input stage that includes two pairs of input differential transistors whose sources are commonly connected for each pair; two constant-current sources that are connected to the common sources of the two pairs of input differential transistors, respectively; a load element that is commonly connected to drain sides of the two pairs of input differential transistors and that performs a current-voltage conversion; and an output stage that is connected to a point where the differential input stage and the load element are connected to each other, wherein the feedback voltage of the output voltage and a slope compensating waveform signal are input to input terminals, respectively, of one of the two pairs of input differential transistors, and voltages at both ends of a current detecting resistor are input to input terminals, respectively, of the other of the two pairs of input differential transistors, the current detecting resistor being connected in series to the inductor.

According to the configuration, the comparator can operate as a comparator having a built-in current detecting amplifier. Therefore, it is not necessary to provide a current detecting amplifier separately from the comparator, and a chip size can be reduced in the case where the control circuit having the built-in comparator is formed into a semiconductor integrated circuit.

In addition, the comparator may further comprises a cascode stage that is connected to drain terminals of the pairs of input differential transistors in a folded-cascode configuration. Such a configuration makes it possible to expand the range of voltage to be input to the pairs of input differential transistors.

Another invention of the present application is configured as a current mode control DC/DC converter comprising: an inductor that is connected between a voltage input terminal to which a DC voltage is input and an output terminal to which a load is connected; a driving element that allows a current to pass through the inductor; a current detecting resistor that is connected in series to the inductor; a voltage control loop that includes a comparator and that controls the driving element according to a feedback voltage of an output voltage; and a loop that feeds back a detection signal of the current passing through the inductor to the voltage control loop, wherein the comparator includes: a differential input stage that includes two pairs of input differential transistors whose sources are commonly connected for each pair; two constant-current sources that are connected to the common sources of the two pairs of input differential transistors, respectively; a load element that is commonly connected to drain sides of the two pairs of input differential transistors and that performs a current-voltage conversion; and an output stage that is connected to a point where the differential input stage and the load element are connected to each other; and wherein the feedback voltage of the output voltage and a slope compensating waveform signal are input to input terminals, respectively, of one of the two pairs of input differential transistors, and voltages at both ends of the current detecting resistor are input to input terminals, respectively, of the other of the two pairs of input differential transistors.

According to the configuration, it is not necessary to provide a high-slew-rate and wideband current detecting amplifier separately from the comparator, so that the cost increase can be avoided. Additionally, a current mode control DC/DC converter, which responds to the current detection signal even when a switching frequency of the driven element is high, can be obtained because the need for a current detecting amplifier is obviated. In addition, the comparator may further include a cascode stage that is connected to drain terminals of the pairs of input differential transistors in a folded-cascode configuration.

Preferably, when the driving element is connected between the voltage input terminal and the inductor, the current detecting resistor is connected between the voltage input terminal and the inductor in such a way that the current detecting resistor is connected in series to the driving element. Such a configuration makes it possible to reduce a power loss because a current is allowed to pass through the current detecting resistor only when the driving element is on, and because the period of time in which a current is allowed to pass through the resistor is shortened compared with a DC/DC converter in which a current sense resistor is connected between the inductor and the output terminal.

More preferably, the current detecting resistor is an on-resistance of the driving element, and voltages at both ends of the driving element are input to the comparator. Such a configuration makes it possible to further reduce a power loss and to obviate the need for a current detecting resistor.

### Effects of the Invention

According to the invention, the PWM comparator advantageously obviates the need for a current detecting differential amplifier which is a factor for the cost increase in the current mode control DC/DC converter.

### BRIEF DESCRIPTION OF DRAWINGS

FIG. 1 is a circuit diagram illustrating a comparator according to an embodiment of the present invention;

FIG. 2 is a circuit diagram illustrating an example of a configuration of a general comparator of the conventional art;

FIG. 3 is a circuit diagram illustrating a comparator according to a modification of the embodiment of the present invention;

FIG. 4 is a block diagram illustrating a configuration of a current mode control DC/DC converter in which the comparator of the present invention is used as a PWM comparator; and

FIG. 5 is a block diagram illustrating a current mode control DC/DC converter that was studied prior to the present invention.

### BEST MODE FOR CARRYING OUT THE INVENTION

Hereinafter, preferred embodiments of the present invention are described below with reference to the drawings.

FIG. 1 illustrates a comparator according to an embodiment of the present invention.

The comparator of the embodiment includes a pair of input differential transistors Q1 and Q2 whose sources are commonly connected and, likewise, a pair of input differential transistors Q3 and Q4 whose sources are commonly connected. Constant current transistors Q5 and Q6 are connected between the respective common sources of the pairs of the input differential transistors and a ground point. On drain sides of the input differential transistors Q1 to Q4, transistors Q7 and Q8 connected in a current-mirror configuration are connected as a load common to the two pairs of input differential transistors.

The transistors Q5 and Q6 operate as constant-current sources, where predetermined voltages Vc1 and Vc2 are applied to the gate terminals of the transistors Q5 and Q6, respectively. The amount of currents which are allowed to pass by the transistors Q5 and Q6 maybe the same or may be different from each other. That is, the gate voltages may be Vc1=Vc2 or Vc1≠Vc2. Alternatively, a predetermined current may be allowed to pass through the constant current transistors Q5 and Q6 in such a way that the constant current transistors Q5 and Q6 and a diode-connected current-voltage transistor in a bias circuit, through which a constant current passes, constitute a current-mirror circuit.

Of the load transistors Q7 and Q8, the load transistor Q8, whose gate and drain are not connected with each other, has the drain to which the gate of a transistor Q11 of an output stage composed of series-connected transistors Q11 and Q12 is connected. The drain terminal of the transistor Q11 is connected to an output terminal OUT. A predetermined constant voltage supplied from a bias circuit (not illustrated) is applied to the gate of the transistor Q12, i.e., the other of the output stage, and the transistor Q12 acts as a constant-current source.

In the comparator of the embodiment, the input differential transistors Q1 to Q4 and the constant current transistors Q5 and Q6 act as a voltage-current conversion unit that passes currents In and Ip according to an input voltage difference. The load transistors Q7 and Q8 and the transistors Q11 and Q12 of the output stage act as a current-voltage conversion unit.

In the embodiment, N-channel metal-oxide semiconductor field effect transistors (MOSFETs) (insulated gate field effect transistors) are used as the transistors Q1 to Q6 and Q12, and P-channel MOSFETs are used as the transistors Q7, Q8, and Q11. However, alternatively, NPN bipolar transistors may be used instead of the N-channel MOSFETs and PNP bipolar transistors may be used instead of the P-channel MOSFETs.

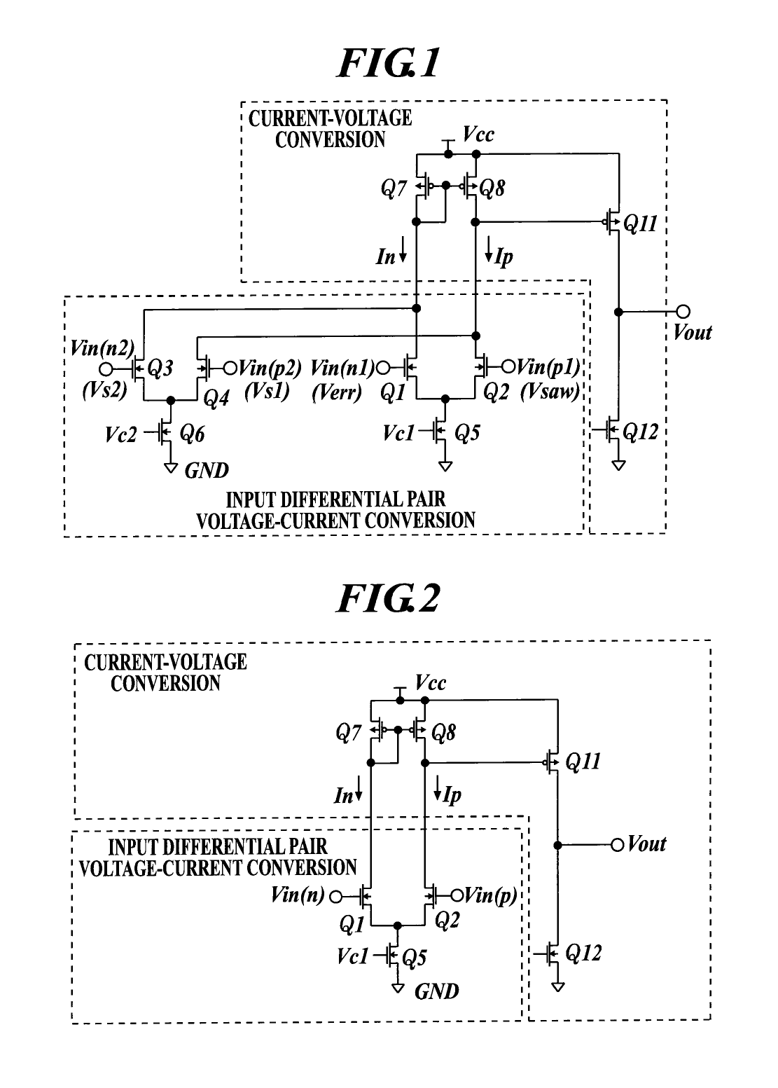

Before explaining features of the comparator of the embodiment, a general comparator illustrated in FIG. 2 will be described. The comparator of FIG. 2 is a circuit including a pair of input differential transistors Q1 and Q2. In the comparator, a conversion in a voltage-current conversion unit is expressed by an equation (2):

ΔI=Gm·ΔV (2)

wherein ΔV is a potential difference between a pair of input voltages Vin(n) and Vin(p), ΔI is a difference between the currents In and Ip passing through the transistors Q1 and Q2, and Gm is a transconductance coefficient of the pair of input differential transistors Q1 and Q2. The current-voltage conversion unit outputs a high level (Vcc) when ΔI is positive, and the current-voltage conversion unit outputs a low level (GND) when ΔI is negative.

On the other hand, in the comparator of the embodiment of FIG. 1, the conversion in the voltage-current conversion unit is expressed by an equation (3):

ΔI=Gm1(Vin(p1)−Vin(n1))+Gm2(Vin(p2)−Vin(n2)) (3)

Wherein Gm1 is a transconductance coefficient of the pair of input differential transistors Q1 and Q2 receiving inputs Vin(n1) and Vin(p1), respectively, and Gm2 is a transconductance coefficient of the pair of input differential transistors Q3 and Q4 receiving inputs Vin(n2) and Vin(p2), respectively.

The current-voltage conversion unit outputs a high level (Vcc) when ΔI is positive, and the current-voltage conversion unit outputs a low level (GND) when ΔI is negative.

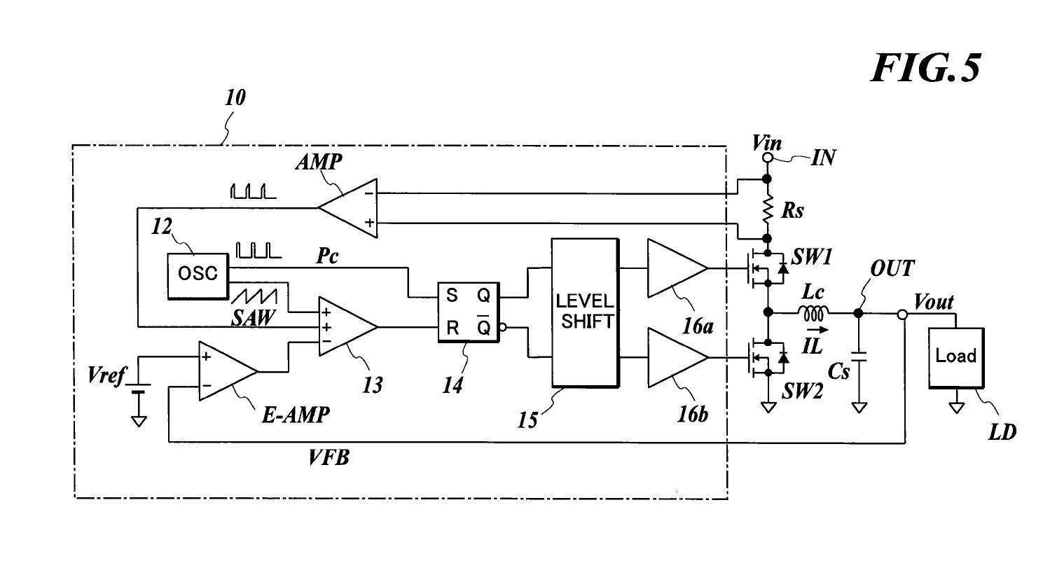

Accordingly, in the case where the comparator of the embodiment is used as the PWM comparator in the current mode control DC/DC converter, the equation (3) is deformed into an equation (4) below:

$$\begin{matrix}Δ I = Gm 1 ( Vsaw - Verr ) + Gm 2 \cdot Vs \\ = Gm 1 \{ ( Gm 2 / Gm 1 ) \cdot Vs + Vsaw - Verr \}\end{matrix} \qquad ( 4 )$$

wherein Vs is a voltage difference (Vs1−Vs2) generated in the current sense resistor Rs when an output Verr of the error amplifier E-AMP of FIG. 5 is input as Vin(n1), the sawtooth wave Vsaw of FIG. 5 is input as Vin(p1), and voltages Vs1 and Vs2 at both the terminals of the current sense resistor Rs are input as Vin(n2) and Vin(p2).

When the equations (1) and (4) are compared to each other, it is found that a ratio Gm2/Gm1 of the transconductance coefficients of the two differential pairs corresponds to the gain Ki of the current detecting amplifier AMP in the DC/DC converter of FIG. 5. Therefore, it is found that the comparator of the embodiment acts as the PWM comparator having the built-in current detecting amplifier in which the gain is Gm2/Gm1.

Therefore, in the current mode control DC/DC converter of FIG. 5, it is not necessary to provide the current detecting amplifier separately from the PWM comparator, and the chip size can be reduced in the case where the control circuit having the built-in PWM comparator is formed into the semiconductor integrated circuit. In the DC/DC converter of FIG. 5 in which the current detecting amplifier is provided, high slew rate and wideband property are desired as the characteristics of the amplifier. Using the comparator of the embodiment eliminates the necessity of the current detecting amplifier, and thereby the cost increase can be avoided. Further, because of the unnecessity of the current detecting amplifier, a response to a current detection signal can be performed even if the switching frequency of the driving element is increased. The value of Gm1/Gm2 can be set based on a current ratio of the constant current transistors Q5 and Q6 of the voltage-current conversion unit having the pairs of input differential transistors.

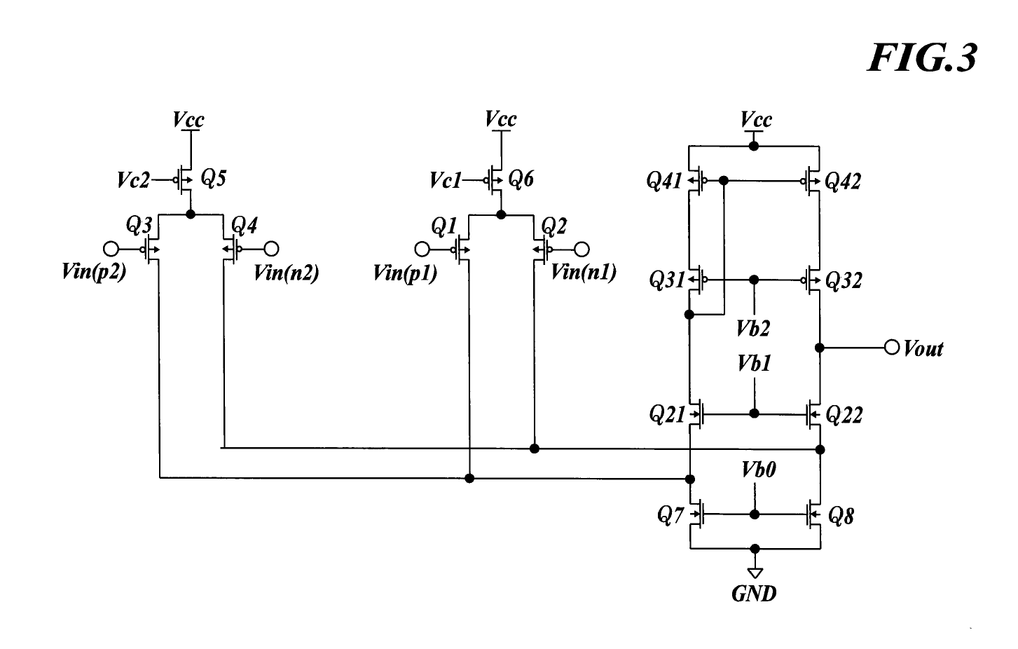

FIG. 3 illustrates a comparator according to a modification of the embodiment. In the comparator of the modification, the P-channel MOSFETs are used as the input differential transistors Q1 to Q4, and a cascode stage including pairs of transistors Q21 and Q22, Q31 and Q32, and Q41 and Q42 that are connected to the differential input stage in a folded-cascode configuration is provided. In each pair of transistors, the gates are commonly connected; predetermined bias voltages Vb0, Vb1, and Vb2 are applied to the common gate terminals, respectively, from a bias circuit (not illustrated), and a potential at an internal node is applied, thereby constituting a current mirror circuit.

The folded cascode type comparator of FIG. 3 has an advantage that the range of voltage to be input to the pairs of input differential transistors can be widened compared with the comparator of FIG. 1. Alternatively, the folded cascade type comparator may be configured so that the N-channel MOSFETs are used as the input differential transistors Q1 to Q4 as illustrated in FIG. 1, instead of using the P-channel MOSFETs, and the constant current transistors Q5 and Q6 are provided on the side of the ground potential GND. Alternatively, the output stage composed of the transistors Q11 and Q12 of FIG. 1 may further be connected subsequent to the cascade stage of FIG. 3.

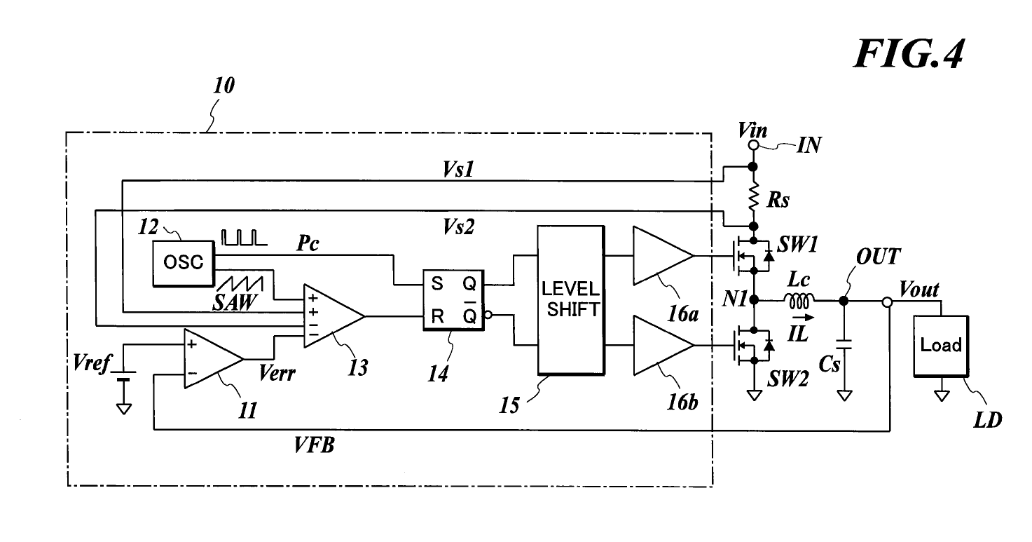

FIG. 4 illustrates an embodiment in which the comparator of the embodiment described above is used as a PWM comparator in the current mode control DC/DC converter having the configuration shown in FIG. 5.

The DC/DC converter of FIG. 4 is constructed as a step-down synchronous rectifying switching regulator that includes a driving switching transistor SW1 and a rectifying switching transistor SW2, a coil (inductor) Lc, a switching control circuit 10, and the like. The driving switching transistor SW1 and the rectifying switching transistor SW2 are composed of the N-channel MOSFETs, and the driving switching transistor SW1 and the rectifying switching transistor SW2 are connected in series between a voltage input terminal IN, to which a DC voltage Vin is input, and the ground point GND. The coil Lc is connected between a connection node N1 of the switching transistors SW1 and SW2 and an output terminal OUT. The switching control circuit 10 performs on/off control on the switching transistors SW1 and SW2. A current sense resistor Rs is connected between the voltage input terminal IN and the driving switching transistor SW1 in order to detect the current passing through the coil Lc via the driving switching transistor SW1. LD is a load which is connected to the output terminal OUT of the DC/DC converter, and Cs is a smoothing condenser.

In the embodiment, the switching control circuit 10 is configured as a control IC on one semiconductor chip. The driving switching transistor SW1 and the rectifying switching transistor SW2 are made up of discrete components and connected to the control IC as external elements, although the invention is not limited to the embodiment. Alternatively, the switching transistors SW1 and SW2 may be formed on the same semiconductor chip as the control IC.

The control IC 10 includes an error amplifier 11, a waveform generating circuit 12, and a PWM comparator 13. The error amplifier 11 amplifies a potential difference between a feedback voltage VFB of the output and a predetermined reference voltage Vref. The waveform generating circuit 12 has a built-in oscillation circuit and generates a slope compensating sawtooth wave SAW and a clock pulse Pc having a predetermined frequency. The sawtooth wave SAW generated by the waveform generating circuit 12, an output of the error amplifier 11, and voltages Vs1 and Vs2 at both the terminals of the current sense resistor RS are input to the PWM comparator 13.

The control IC 10 further includes an RS flip-flop 14, a level-shift circuit 15, and driving circuits (drivers) 16a and 16b. In the RS flip-flop 14, the clock pulse Pc generated by the pulse generator 12 is input to a set terminal, and the output of the PWM comparator 13 is input to a reset terminal. The level-shift circuit 15 performs level shift of outputs Q and /Q of the flip-flop 14. The driving circuits 16a and 16b generates and outputs driving signals to turn on and off the switching transistors SW1 and SW2 based on the level-shifted signals.

In the DC/DC converter of FIG. 4, the flip-flop 14 is set by the clock pulse Pc, and the driving switching transistor SW1 is turned on, thereby starting one cycle. When the switching transistor SW1 is turned on, a current IL to be allowed to pass through the coil (inductor) is increased, and a peak value of the current IL is controlled based on a feedback signal from the output voltage, namely, the output of the error amplifier 11. More specifically, the detection voltage of the current IL is compared to the output of the error amplifier 11. When the detection voltage of the current IL matches the output of the error amplifier 11, control is performed so that the output of the PWM comparator 13 is inverted, the flip-flop 14 is reset, and the driving switching transistor SW1 is turned off.

Although the current sense resistor Rs is connected between the DC voltage input terminal IN and the driving switching transistor SW1 in the embodiment, the current sense resistor Rs may be connected between the coil Lc and the output terminal OUT in such a way that the current sense resistor Rs is connected in series to the coil Lc. However, in the case where the current sense resistor Rs is connected between the coil Lc and the output terminal OUT, the current is allowed to pass through the coil and resistor even in the period in which the transistor SW1 is off. On the other hand, in the case where the current sense resistor Rs is connected between the voltage input terminal IN and the transistor SW1, like the DC/DC converter of the embodiment of FIG. 4, advantageously the power loss is reduced because the current is allowed to pass through the resistor only in the period in which the transistor SW1 is on. When the current sense resistor Rs is connected between the connection point N1 where the coil Lc and the rectifying transistor SW2 are connected to each other, and the transistor SW1, the power loss is reduced similarly to the embodiment of FIG. 4.

An on-resistance of the driving switching transistor SW1 may be used in place of the current sense resistor, whereby the power loss is further reduced. In this case, the voltages at both the ends of the driving switching transistor SW1 may be input to the comparator 13 only in the period in which the driving switching transistor SW1 is on.

The present invention made by the inventor has been concretely described above based on the embodiments. However, the invention is not limited to the embodiments. For example, the switching control circuit 10 to which the comparator of the present invention can be applied is not limited to the configuration shown in FIG. 4. The switching control circuit 10 may be configured so that a one-shot multivibrator is used instead of the flip-flop 14 or may be configured so that the level-shift circuit 15 is omitted.

Further, although the output voltage Vout is directly input to the error amplifier 11 in the DC/DC converter of FIG. 4, a series resistor that divides the output voltage Vout may alternatively be provided and the divided voltage may be input as a feedback voltage to the error amplifier 11.

### INDUSTRIAL APPLICABILITY

In the above description, the present invention is applied to the step-down DC/DC converter. Alternatively, the invention may also be applied to a step-up DC/DC converter. Further, although the present invention is applied to the DC/DC converter that is of a synchronous rectifying switching regulator in the embodiments, the invention may alternatively be applied to a diode rectifying DC/DC converter in which a diode is used as a rectifying element.

### REFERENCE NUMERALS

10 switching control circuit (control IC)

11 error amplifier

12 waveform generating circuit

13 PWM comparator

14 flip-flop

15 level-shift circuit

16a, 16b driving circuit

LD load

Lc coil (inductor)

Cs smoothing condenser

SW1 coil driving switching transistor

SW2 rectifying switching transistor

AMP current detecting differential amplifier

E-AMP error amplifier

1. A comparator to be provided in a voltage control loop of a current mode control DC/DC converter including an inductor that is connected between a voltage input terminal to which a DC voltage is input and an output terminal to which a load is connected, a driving element that allows a current to pass through the inductor, the voltage control loop controlling the driving element according to a feedback voltage of an output voltage, a current detecting resistor that is connected in series to the inductor, and a loop that feeds back a detection signal of the current passing through the inductor to the voltage control loop, the comparator comprising:
a differential input stage that includes two pairs of input differential transistors whose sources are commonly connected for each pair;
two constant-current sources that are connected to the common sources of the two pairs of input differential transistors, respectively;
a load element that is commonly connected to drain sides of the two pairs of input differential transistors and that performs a current-voltage conversion; and
an output stage that is connected to a point where the differential input stage and the load element are connected to each other,
wherein the feedback voltage of the output voltage and a slope compensating waveform signal are input to input terminals, respectively, of one of the two pairs of input differential transistors, and voltages at both ends of the current detecting resistor are input to input terminals, respectively, of the other of the two pairs of input differential transistors.

2. The comparator according to claim 1, further comprising a cascode stage that is connected to drain terminals of the pairs of input differential transistors in a folded-cascode configuration.

3. A current mode control DC/DC converter comprising:
an inductor that is connected between a voltage input terminal to which a DC voltage is input and an output terminal to which a load is connected;
a driving element that allows a current to pass through the inductor;
a current detecting resistor that is connected in series to the inductor;
a voltage control loop that includes a comparator and that controls the driving element according to a feedback voltage of an output voltage;
wherein the comparator includes:
a differential input stage that includes two pairs of input differential transistors whose sources are commonly connected for each pair;
two constant-current sources that are connected to the common sources of the two pairs of input differential transistors, respectively;
a load element that is commonly connected to drain sides of the two pairs of input differential transistors and that performs a current-voltage conversion; and
an output stage that is connected to a point where the differential input stage and the load element are connected to each other;
wherein the converter further comprises a loop that feeds back a detection signal of the current passing through the inductor to the voltage control loop; and
wherein the feedback voltage of the output voltage and a slope compensating waveform signal are input to input terminals, respectively, of one of the two pairs of input differential transistors, and voltages at both ends of the current detecting resistor are input to input terminals, respectively, of the other of the two pairs of input differential transistors.

4. The DC/DC converter according to claim 3, wherein the comparator further includes a cascode stage that is connected to drain terminals of the pairs of input differential transistors in a folded-cascode configuration.

5. The DC/DC converter according to claim 3, wherein, when the driving element is connected between the voltage input terminal and the inductor, the current detecting resistor is connected between the voltage input terminal and the inductor in such a way that the current detecting resistor is connected in series to the driving element.

6. The DC/DC converter according to claim 3, wherein the current detecting resistor is an on-resistance of the driving element, and voltages at both ends of the driving element are input to the input terminals, respectively, of the other of the pairs of input differential transistors.

7. The DC/DC converter according to claim 4, wherein, when the driving element is connected between the voltage input terminal and the inductor, the current detecting resistor is connected between the voltage input terminal and the inductor in such a way that the current detecting resistor is connected in series to the driving element.

8. The DC/DC converter according to claim 4, wherein the current detecting resistor is an on-resistance of the driving element, and voltages at both ends of the driving element are input to the input terminals, respectively, of the other of the pairs of input differential transistors.
